(19) United States
(12) Patent Application Publication
(10) Pub. No.: US 2023/0154860 A1
(43) Pub. Date: May 18, 2023

(54) SEMICONDUCTOR CHIP INCLUDING ALIGN MARK PROTECTION PATTERN AND SEMICONDUCTOR PACKAGE INCLUDING SEMICONDUCTOR CHIP INCLUDING THE ALIGN MARK PROTECTION PATTERN

(71) Applicant: SK hynix Inc., Icheon-si Gyeonggi-do (KR)

(72) Inventor: Hyun Chul SEO, Icheon-si Gyeonggi-do (KR)

(73) Assignee: SK hynix Inc., Icheon-si Gyeonggi-do (KR)

(21) Appl. No.: 17/707,619

(22) Filed: Mar. 29, 2022

(30) Foreign Application Priority Data
Nov. 15, 2021 (KR) 10-2021-0157051

(51) Int. Cl. H01L 23/544; H01L 23/31; H01L 23/00

(52) U.S. Cl. CPC H01L 23/544; H01L 23/3157; H01L 24/32; H01L 2224/32113; H01L 2924/01079; H01L 2924/0105; H01L 2924/01029

(57) ABSTRACT

A semiconductor chip includes a chip body, a redistribution layer pattern disposed on a surface of the chip body, an alignment mark pattern disposed to be spaced apart from the redistribution layer pattern on the surface of the chip body, a first insulating pattern disposed to contact a side surface of the redistribution layer pattern and a side surface of the alignment mark pattern on the surface of the chip body, a second insulating pattern disposed on the redistribution layer pattern to protect the redistribution layer pattern, and an alignment mark protection pattern disposed on the alignment mark pattern.

### CROSS-REFERENCE TO RELATED APPLICATIONS

The present application claims priority under 35 U.S.C 119(a) to Korean Application No. 10-2021-0157051, filed on Nov. 15, 2021, which is incorporated herein by reference in its entirety.

### BACKGROUND

### 1. Technical Field

The present disclosure generally relates to a semiconductor chip including an align mark protection pattern and a semiconductor package including the semiconductor chip including the align mark protection pattern.

### 2. Related Art

A semiconductor package manufacturing process may include a process of separating a wafer on which a semiconductor integration process has been completed in a semiconductor chip unit, a process of mounting the semiconductor chip on a package substrate and electrically connecting the semiconductor chip and the package substrate, a process of molding the semiconductor chip on the package substrate, and a process of forming a solder connection structure on a connection pad disposed on a surface of the package substrate.

Meanwhile, among the semiconductor package manufacturing processes, the process of mounting the semiconductor chip separated from the wafer on the package substrate may include a process of inspecting the degree of alignment between the semiconductor chip and a predetermined position in order to seat the semiconductor chip at the predetermined position on the package substrate. For example, the inspection process may be performed by determining the degree of alignment between alignment marks disposed on the semiconductor chip and alignment marks disposed on the package substrate. Thus, during the inspection process, the alignment marks on the semiconductor chip need to remain uncontaminated so that their images can be sufficiently identified by an inspection device.

### SUMMARY

A semiconductor chip according to an embodiment of the present disclosure may include a chip body, a redistribution layer pattern disposed on a surface of the chip body, an alignment mark pattern disposed to be spaced apart from the redistribution layer pattern on the surface of the chip body, a first insulating pattern disposed to contact a side surface of the redistribution layer pattern and a side surface of the alignment mark pattern on the surface of the chip body, a second insulating pattern disposed on the redistribution layer pattern to protect the redistribution layer pattern, and an alignment mark protection pattern disposed on the alignment mark pattern.

A semiconductor chip according to another embodiment of the present disclosure may include a chip body, a redistribution layer pattern and an alignment mark pattern that are disposed to be spaced apart from each other on a surface of the chip body, an insulating pattern disposed on the redistribution layer pattern, and an alignment mark protection pattern disposed on the alignment mark pattern. The alignment mark protection pattern may include a metal material. The alignment mark protection pattern may offset a height difference between the alignment mark pattern and the insulating pattern.

A semiconductor package according to another embodiment of the present disclosure may include a package substrate, and a semiconductor chip mounted over the package substrate and including an alignment mark pattern for alignment over the package substrate. The semiconductor chip may include a chip body, a redistribution layer pattern disposed on a surface of the chip body, an alignment mark pattern disposed to be spaced apart from the redistribution layer pattern on the surface of the chip body, a first insulating pattern disposed to contact a side surface of the redistribution layer pattern and a side surface of the alignment mark pattern on the surface of the chip body, a second insulating pattern disposed on the redistribution layer pattern to protect the redistribution layer pattern, and an alignment mark protection pattern disposed on the alignment mark pattern and offsetting a height difference between the second insulating pattern and the alignment mark pattern.

### BRIEF DESCRIPTION OF THE DRAWINGS

FIG. 1 is a plan view schematically illustrating a semiconductor chip according to an embodiment of the present disclosure.

FIG. 2 is an enlarged plan view of an edge region of the semiconductor chip of FIG. 1.

FIG. 3 is a cross-sectional view illustrating the edge region of the semiconductor chip of FIG. 2 taken along line I-I′.

FIG. 4 is a cross-sectional view illustrating the edge region of the semiconductor chip of FIG. 2 taken along line II-II′.

FIGS. 5, 6, 7, 8, 9, and 10 are cross-sectional views schematically illustrating a method of manufacturing a semiconductor package according to an embodiment of the present disclosure.

FIG. 11 is a cross-sectional view illustrating a manufacturing process of the semiconductor package of FIG. 7.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof. It will be understood that when an element, body, pattern, or layer is referred to as being “on,” “connected to” or “coupled to” another element, body, pattern, or layer, it can be directly on, connected or coupled to the other element, body, pattern, or layer or intervening elements, body, pattern, or layers may be present. In contrast, when an element is referred to as being “directly on,” “directly connected to” or “directly coupled to” another element, body, pattern, or layer, there are no intervening elements, body, pattern, or layers present.

The semiconductor package may include electronic devices such as a semiconductor chip, and the semiconductor chip may include a semiconductor substrate on which an electronic circuit is integrated, which is cut and processed in the form of a chip. A semiconductor chip may mean a memory chip in which a memory integrated circuit such as dynamic random access memory (DRAM), static random access memory (SRAM), NAND flash memory (NAND FLASH), NOR flash memory (NOR FLASH), magnetoresistive random-access memory (MRAM), resistive random-access memory (ReRAM), ferroelectric random-access memory (FeRAM) or phase-change random-access memory (PcRAM) is integrated, or a logic chip in which a logic circuit is integrated on a semiconductor substrate, or an application-specific integrated circuit (ASIC) chip. Meanwhile, the semiconductor chip may be referred to as a semiconductor die.

The semiconductor package may include a printed circuit board (PCB) on which the semiconductor chip is mounted. The printed circuit board (PCB) may include at least one layer or more of an integrated circuit pattern, and may be referred to as a package substrate in the present specification. For communication between the package substrate and the semiconductor chip, a connection method such as wire bonding may be applied.

The semiconductor package may be applied to various electronic information processing devices, for example, information communication devices such as portable terminals, bio or health care related electronic devices, and human wearable electronic devices.

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

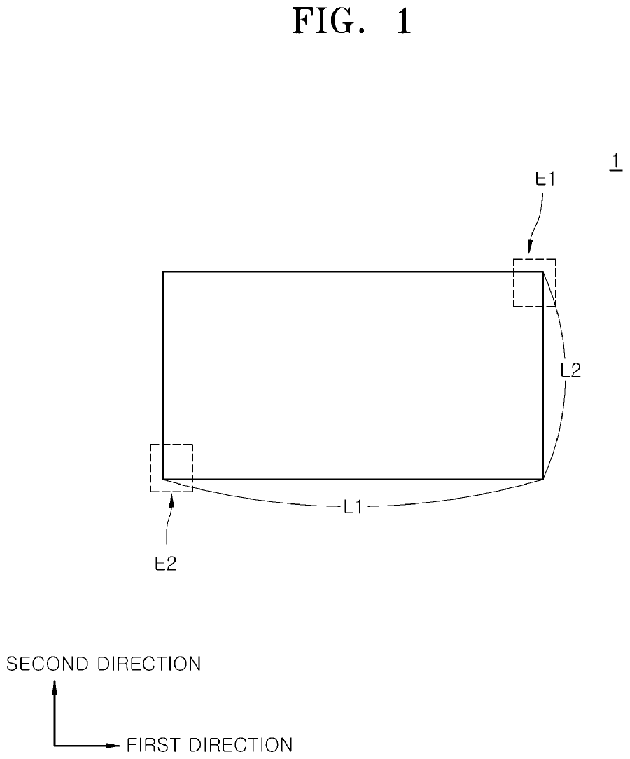

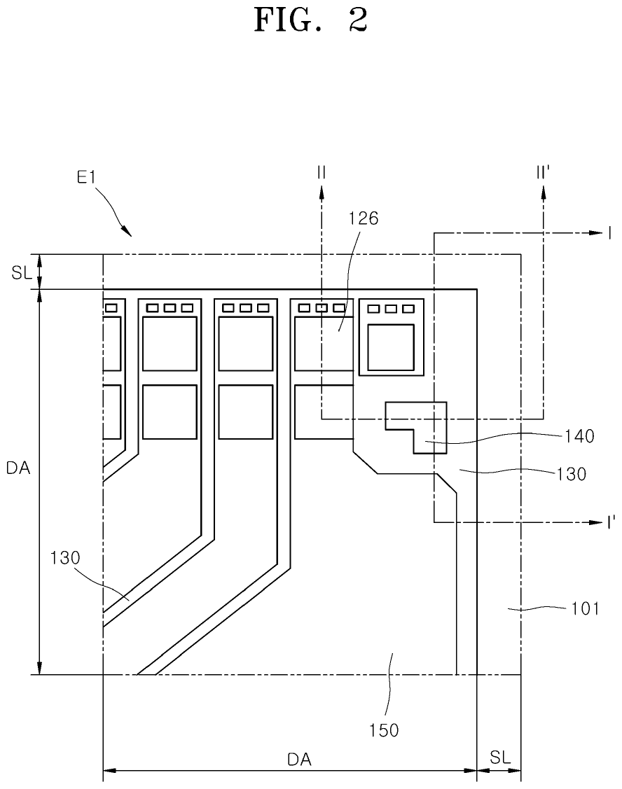

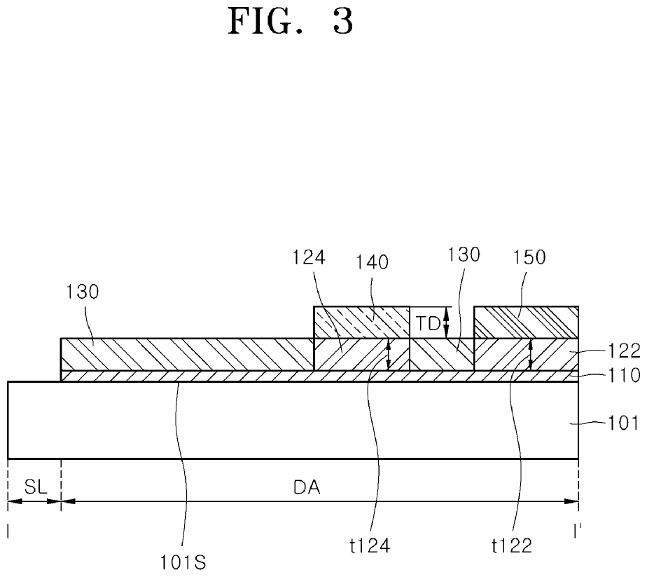

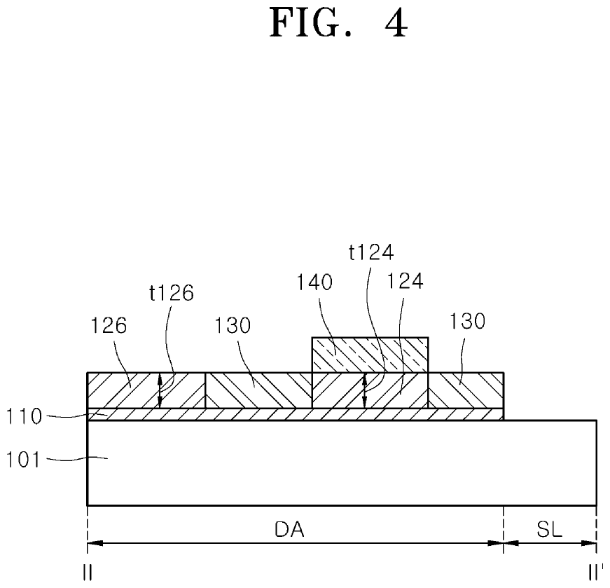

FIG. 1 is a plan view schematically illustrating a semiconductor chip according to an embodiment of the present disclosure. FIG. 2 is an enlarged plan view of an edge region of the semiconductor chip of FIG. 1. FIG. 3 is a cross-sectional view illustrating the edge region of the semiconductor chip of FIG. 2 taken along line I-I′. FIG. 4 is a cross-sectional view illustrating the edge region of the semiconductor chip of FIG. 2 taken along line II-II′.

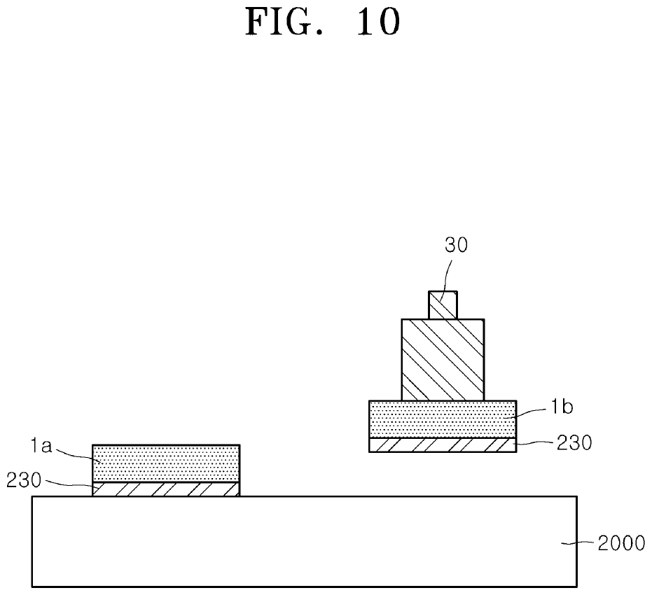

Referring to FIG. 1 and FIG. 10, the semiconductor chip 1 may have a rectangular shape including long sides L1 and short sides L2. As will be described later with reference to FIGS. 2 to 4, the semiconductor chip 1 may have alignment mark patterns (not shown) and alignment mark protection patterns (not shown) disposed in first and second edge regions E1 and E2 near the corners where the long sides L1 and the short sides L2 meet. The alignment mark patterns may be used as alignment means for seating the semiconductor chips 1a and 1b at predetermined positions on the package substrate 2000 without error. The semiconductor chips 1a and 1b may be respectively seated at the predetermined positions on the package substrate 2000 by monitoring the degree of alignment between the alignment mark patterns disposed on each of the semiconductor chips 1a and 1b and the alignment mark patterns disposed on the package substrate 2000 and correcting the position error. In addition, the alignment mark protection pattern may serve to protect the alignment mark patterns from contamination generated during packaging processes to be described later. The word “predetermined” as used herein with respect to a parameter, such as a predetermined position, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

FIG. 2 is an enlarged plan view of the edge region E1 of the semiconductor chip of FIG. 1. FIGS. 3 and 4 are cross-sectional views illustrating the edge region E1 of the semiconductor chip of FIG. 2 taken along lines I-I′ and II-II′, respectively.

Referring to FIGS. 2 to 4, the semiconductor chip (1 of FIG. 1) may include a chip body 101. The chip body 101 may include a device area DA in which an integrated circuit constituting the semiconductor chip 1 is disposed, and a scribe lane area SL disposed outside the device area DA. The scribe lane area SL may be an area electrically separated from the device area DA. Although not shown in FIGS. 2 to 4, in the device area DA of the chip body 101, a plurality of integrated circuit pattern layers performing various functions of the semiconductor chip 1, a plurality of wires connecting the plurality of integrated circuit pattern layers to each other, and insulating layers disposed between the plurality of integrated circuit pattern layers and the plurality of wirings.

The scribe lane area SL may be disposed along the circumference of the semiconductor chip 1 in the edge region E1 of the semiconductor chip 1 of FIG. 1. Although not shown in FIGS. 2 to 4, various test patterns may be disposed in the scribe lane area SL. For example, the test patterns may include patterns for monitoring semiconductor processes or patterns for evaluating electrical characteristics of a unit integrated circuit.

Referring to FIGS. 3 and 4, a base insulating layer 110 may be disposed on a surface 101S of the chip body 101 located in the device area DA. The base insulating layer 110 may perform a function of electrically insulating conductive patterns formed on the chip body 101 from the chip body 101. The base insulating layer 110 may include, for example, oxide, nitride, or oxynitride.

First to third conductive patterns 122, 124, and 126 may be disposed on the base insulating layer 110. The first conductive pattern 122 may be a redistribution layer pattern 122. That is, the redistribution layer pattern 122 may correspond to a portion of a wiring that electrically connects the integrated circuit pattern layer inside the chip body 101 to various types of connection structures disposed on the base insulating layer 110. The second conductive pattern 124 may be an alignment mark pattern 124. As described above, the alignment mark pattern 124 may be an alignment pattern formed for alignment between the semiconductor chip 1 and the package substrate (not shown). The alignment mark pattern 124 may be spaced apart from the redistribution layer pattern 122 to be electrically insulated from the redistribution layer pattern 122. The third conductive pattern 126 may be a connection pad 126. The connection pad 126 may be a connection structure disposed for electrical connection of the semiconductor chip 1 and the package substrate. For example, the connection pad 126 of the semiconductor chip 1 may be electrically connected to a connection pad of the package substrate by a wire bonding method. The connection pad 126 may be electrically connected to the redistribution layer pattern 122. The connection pad 126 may be electrically connected to the integrated circuit pattern layer inside the chip body 101 through the redistribution layer pattern 122.

Each of the redistribution layer pattern 122, the alignment mark pattern 124, and the connection pad 126 may include a metal material. For example, each of the redistribution layer pattern 122, the alignment mark pattern 124, and the connection pad 126 may be a metal plating pattern. In an embodiment, the redistribution layer pattern 122, the alignment mark pattern 124, and the connection pad 126 may be formed of the same material. In an embodiment, the redistribution layer pattern 122, the alignment mark pattern 124, and the connection pad 126 may have substantially the same thickness. Referring to FIG. 2, a thickness t122 of the redistribution layer pattern 122 may be substantially identical to a thickness of the alignment mark pattern 124. Referring to FIG. 3, a thickness of the connection pad 126 may be substantially identical to the thickness of the alignment mark pattern 124.

Referring to FIGS. 2 to 4, a first insulating pattern 130 may be disposed on the base insulating layer 110 to contact a side surface of the redistribution layer pattern 122, a side surface of the alignment mark pattern 124, and a side surface of the connection pad 126. The first insulating pattern 130 may be disposed to surround the alignment mark pattern 124. The first insulating pattern 130 may include, for example, oxide, nitride, or oxynitride.

Referring to FIGS. 2 to 4, a second insulating pattern 150 may be disposed on the redistribution layer pattern 122. The second insulating pattern 150 may function to protect the redistribution layer pattern 122. The second insulating pattern 150 might not be disposed on the alignment mark pattern 124 and the connection pad 126. Accordingly, a height difference TD may be formed between an upper surface of the second insulating pattern 150 and an upper surface of the alignment mark pattern 124 and between the upper surface of the second insulating pattern 150 and an upper surface of the connection pad 126.

An alignment mark protection pattern 140 may be disposed on the alignment mark pattern 124. The alignment mark protection pattern 140 may be disposed to cover a surface of the alignment mark pattern 124. The alignment mark protection pattern 140 may be disposed to contact the alignment mark pattern 124. In an embodiment, the alignment mark protection pattern 140 and the alignment mark pattern 124 may be disposed to overlap with each other over the base insulating layer 110. Accordingly, the shape of the alignment mark protection pattern 140 may be substantially the same as the shape of the alignment mark pattern 124.

The alignment mark protection pattern 140 may be formed of a material having superior light reflection characteristics compared to the first and second insulating patterns 130 and 150. In an embodiment, the alignment mark protection pattern 140 may include a metal material.

In an embodiment, the alignment mark protection pattern 140 may include a metal plating layer. The metal plating layer may include, for example, copper (Cu), tin (Sn), gold (Au), or a combination of two or more thereof. The metal plating layer may be, for example, a solder material. The alignment mark protection pattern 140 may be formed by forming a photosensitive thin film including a hole exposing the alignment mark pattern 124 and forming a metal plating layer inside the hole using a plating method including electrolytic plating, electroless plating, or a combination of two or more thereof. In an embodiment in which the electroplating method is applied, a plating seed layer for electroplating may be previously formed inside the hole before performing the electroplating. In some other embodiments, the alignment mark protection pattern 140 may be formed by a printing method such as a stencil printing method. In this case, the alignment mark protection pattern 140 may include a solder material.

The alignment mark protection pattern 140 may function to offset the height difference TD between the alignment mark pattern 124 and the second insulating pattern 150. For example, the upper surface of the alignment mark protection pattern 140 may be positioned at substantially the same level as the upper surface of the second insulating pattern 150. Accordingly, the alignment mark protection pattern 140 disposed on the alignment mark pattern 124 may remove the height difference TD. For example, in an embodiment, the alignment mark protection pattern 140 offsets a height difference TD between an upper surface of the alignment mark pattern 124 and an upper surface of the second insulating pattern 150 as, for example, illustrated in FIG. 3. In an embodiment, the redistribution layer pattern 122 and the alignment mark pattern 124 may have substantially the same thickness, and the alignment mark protection pattern 140 and the second insulating pattern 150 may have substantially the same thickness. In an embodiment, having the redistribution layer pattern 122 and the alignment mark pattern 124 at substantially the same thickness and the alignment mark protection pattern 140 and the second insulating pattern 150 at substantially the same thickness may allow the alignment mark protection pattern to offset a height difference between an upper surface of the alignment mark pattern and an upper surface of the second insulating pattern.

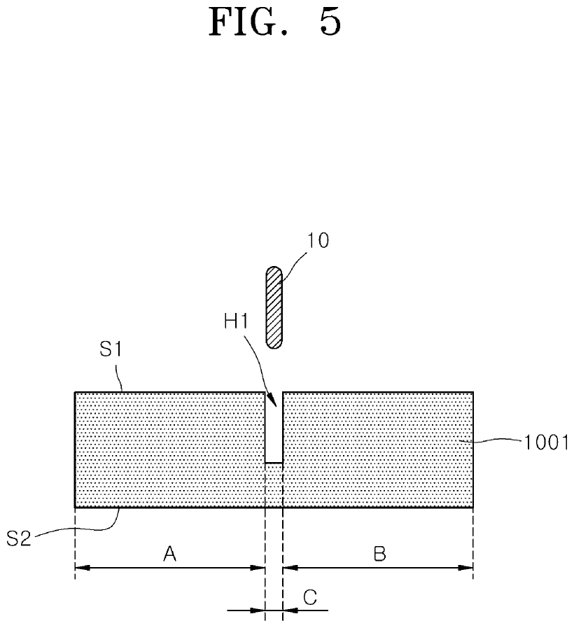

In addition, in an embodiment, the alignment mark protection pattern 140 may serve to protect the alignment mark pattern 124 during the semiconductor package processes. In an embodiment, during the semiconductor package processes described later with reference to FIGS. 5 to 11, the alignment mark protection pattern 140 may serve to protect the alignment mark pattern 124 from external contamination sources.

Referring to FIGS. 2 and 4, the connection pad 126 may be exposed to the outside for bonding with a connection structure such as a bonding wire. That is, an insulating pattern or a protection pattern might not be disposed on the connection pad 126.

As described above, using FIGS. 2 to 4, the configuration of the first edge region E1 of the semiconductor chip 1 of FIG. 1 may be disclosed. Although not shown, the configuration of the second edge region E2 of the semiconductor chip 1 of FIG. 1 may be substantially the same as the configuration of the first edge region E1. That is, in the second edge region E2, the base insulating layer 110 may be disposed on the surface 101S of the chip body 101. A redistribution layer pattern, an alignment mark pattern, and a connection pad may be disposed on the base insulating layer 110 to be spaced apart from each other. In addition, a first insulating pattern may be disposed to contact side surfaces of the redistribution layer pattern, the alignment mark pattern, and the connection pad. A second insulating pattern may be disposed on the redistribution layer pattern, and an alignment mark protection pattern may be disposed on the alignment mark pattern. The configurations of the redistribution layer pattern, the alignment mark pattern, the connection pad, the first and second insulating patterns, and the alignment mark protection pattern may be substantially the same as the configurations of the redistribution layer pattern 122, the alignment mark pattern 124, the connection pad 126, the first and second insulating patterns 130 and 150, and the alignment mark protection pattern 140 of FIGS. 2 to 4.

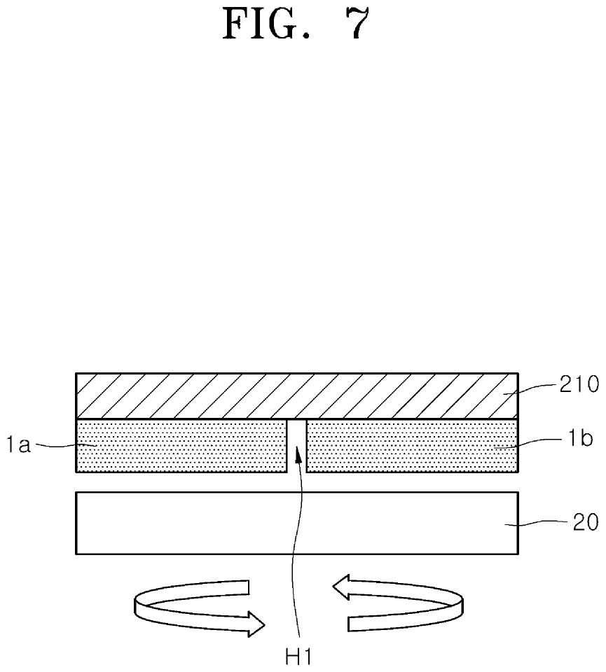

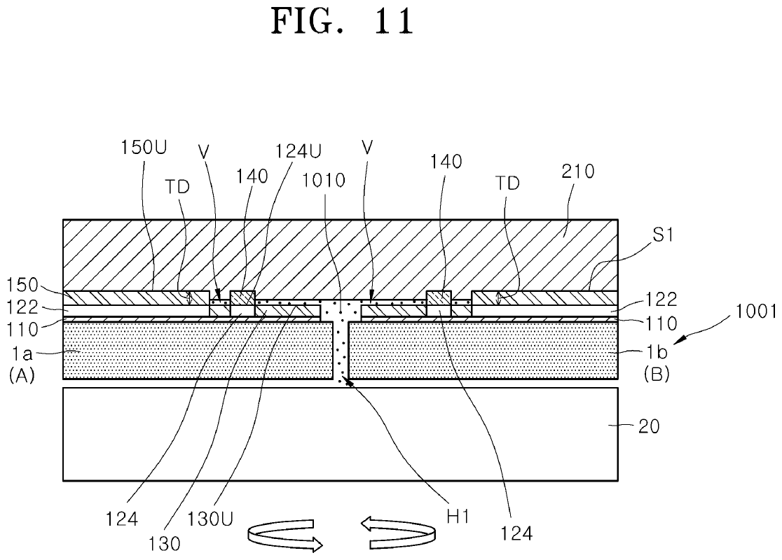

FIGS. 5 to 10 are cross-sectional views schematically illustrating a method of manufacturing a semiconductor package according to an embodiment of the present disclosure. FIG. 11 is a cross-sectional view illustrating the manufacturing process of the semiconductor package of FIG. 7.

Referring to FIG. 5, a wafer 1001 including integrated circuit pattern layers formed by semiconductor manufacturing processes may be provided. The wafer 1001 may include a plurality of chip areas A and B separated by a chip boundary area C. The wafer 1001 may include a front side S1 and a rear side S2 positioned opposite to the front side S1. For example, the integrated circuit pattern layers may be formed in an inner region adjacent to the front side S1 between the front side S1 and the rear side S2.

Referring to FIG. 5, a groove H1 may be formed along the chip boundary area C of the wafer 1001 by using a cutting device 10. The groove H1 may be formed in an inner direction of the wafer 1001 from the surface of the front side S1 of the wafer 1001. That is, the cutting device 10 may partially cut the wafer 1001 in a thickness direction. The depth of the groove H1 may be about half (½) of the thickness of the wafer 1001. The cutting device 10 may include, for example, a blade or a laser.

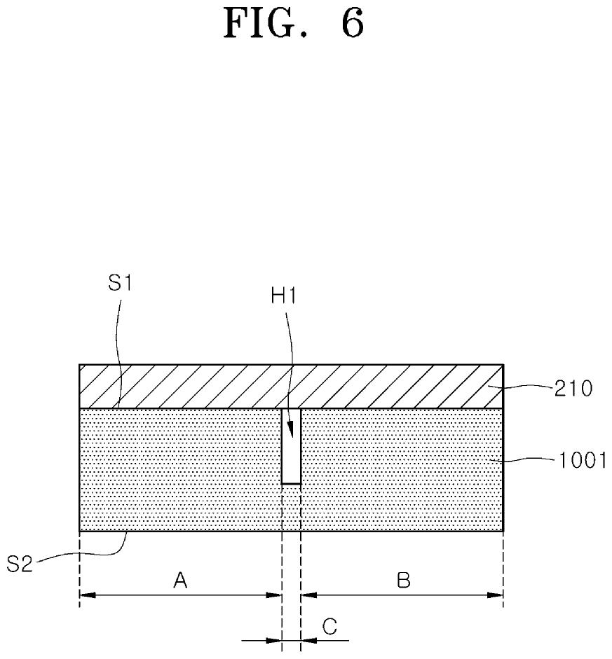

Referring to FIG. 6, a surface protection tape 210 may be attached on the front side S1 of the wafer 1001. Referring to FIG. 7, the plurality of chip areas A and B of the wafer 1001 may be separated from each other by grinding the wafer 1001 in the thickness direction from the rear side S2 of the wafer 1001 while the front side S1 is protected by the surface protection tape 210. Accordingly, the semiconductor chips 1a and 1b that are distinguished from each other may be obtained from the separated chip areas A and B. The process of grinding the wafer 1001 may be performed by rotating a cutting wheel 20 of the grinding device to remove the wafer 1001 in the thickness direction from the rear side S2 of the wafer 1001.

FIG. 11 is a cross-sectional view illustrating the grinding process of FIG. 7. Referring to FIG. 11, process by-products 1010 may be generated in the process of grinding the wafer 1001. The process by-products 1010 may include, for example, silicon (Si) particles or silicon (Si) dust generated by cutting the wafer 1001. Meanwhile, when the chip areas A and B are separated from the wafer 1001, the process by-products 1010 may be introduced into the front side S1 of the wafer 1001 through the groove H1 located at the boundary between the semiconductor chips 1a and 1b.

While grinding the wafer 1001, the front side S1 of the wafer 1001 may maintain a bonding state with the surface protection tape 210. However, as described above with reference to FIGS. 2 to 4, in the edge region E1 of each of the semiconductor chips 1a and 1b, a height difference TD may exist between an upper surface 124U of the alignment mark pattern 124 and an upper surface 150U of the second insulating pattern 150 or between an upper surface 13U of the first insulating pattern 130 and the upper surface 150U of the second insulating pattern 150. Due to the height difference TD, the surface protection tape 210 might not be sufficiently adhered to the first insulating pattern 130, and empty spaces V may be generated between the surface protection tape 210 and the first insulating pattern 130. Accordingly, the process by-products 1010 may be introduced into the empty spaces V from the groove H1.

According to an embodiment of the present disclosure, the alignment mark protection pattern 140 may be disposed on the alignment mark pattern 124, and the alignment mark protection pattern 140 may contact the surface protection tape 210. That is, the alignment mark protection pattern 140 may prevent or mitigate the empty spaces V from being generated between the surface protection tape 210 and the alignment mark pattern 124. In other words, in an embodiment, the alignment mark protection pattern 140 may serve to offset the height difference TD between the second insulating pattern 150 and the alignment mark pattern 124.

Meanwhile, when the alignment mark protection pattern 140 does not exist, the process by-products 1010 introduced into the empty spaces V may settle on the surface of the alignment mark pattern 124. Accordingly, the surface of the alignment mark pattern 124 may be contaminated by the process by-products 1010. If the alignment mark pattern 124 is contaminated, a recognition error may occur when reading an image for the alignment mark pattern 124. As a result, as will be described later with reference to FIG. 10, when an operation of respectively transferring the separated semiconductor chips 1a and 1b to a predetermined positions on the package substrate is performed, an operation error may occur.

As described above, in the embodiment of the present disclosure, the alignment mark protection pattern 140 of the semiconductor chip may serve to protect the alignment mark pattern 124 from the process by-products 1010 during the grinding process with respect to the wafer 1001.

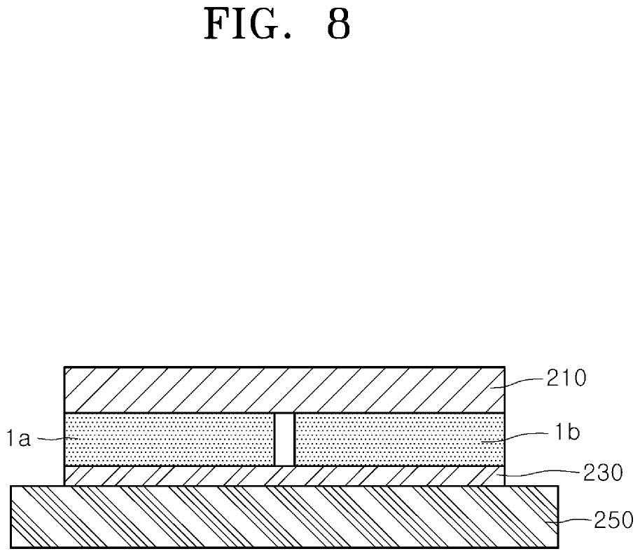

Referring to FIG. 8, the separated semiconductor chips 1a and 1b on the surface protection tape 210 may be attached to a die attach film 230 disposed on a dicing tape 250. Then, the surface protection tape 210 may be detached from the semiconductor chips 1a and 1b.

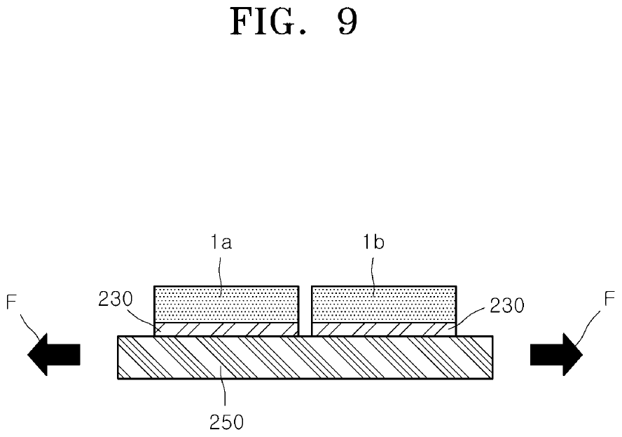

Referring to FIG. 9, the die attach film 230 may be divided by applying a force F to the dicing tape 250 in different lateral directions to expand the dicing tape 250. Accordingly, the semiconductor chips 1a and 1b may be separated from each other while being attached to the die attach film 230 on the dicing tape 250.

Referring to FIG. 10, the semiconductor chips 1a and 1b separated on the dicing tape 250 may be sequentially picked up using a transfer device 30 and seated at predetermined positions of a package substrate 2000. At this time, in an embodiment, by monitoring and correcting the alignment between the alignment mark patterns 124 of the semiconductor chips 1a and 1b and the alignment patterns (not shown) of the package substrate 2000, it is possible to reduce an error in the positions where the semiconductor chips 1a and 1b are seated.

By the above-described method, the semiconductor package according to an embodiment of the present disclosure may be manufactured. According to an embodiment of the present disclosure, a height difference between an alignment mark pattern and an insulating pattern adjacent to each other on a semiconductor chip may be offset by using an alignment mark protection pattern. In addition, in an embodiment, because the alignment mark protection pattern is disposed to cover the alignment mark pattern, it is possible to prevent or mitigate the alignment mark pattern from being contaminated while the semiconductor chip is separated from a wafer. Accordingly, in an embodiment, the reliability of a package process for mounting the semiconductor chip at a predetermined position on a package substrate using the alignment mark pattern may be improved.

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A semiconductor chip comprising:
a chip body;
a redistribution layer pattern disposed on a surface of the chip body;
an alignment mark pattern disposed to be spaced apart from the redistribution layer pattern on the surface of the chip body;
a first insulating pattern disposed to contact a side surface of the redistribution layer pattern and a side surface of the alignment mark pattern on the surface of the chip body;
a second insulating pattern disposed on the redistribution layer pattern to protect the redistribution layer pattern; and
an alignment mark protection pattern disposed on the alignment mark pattern.

2. The semiconductor chip of claim 1, wherein each of the alignment mark pattern and the alignment mark protection pattern includes a metal material.

3. The semiconductor chip of claim 1, wherein the alignment mark protection pattern is disposed to cover the alignment mark pattern.

4. The semiconductor chip of claim 1, wherein the alignment mark protection pattern includes a metal plating layer, and
wherein the metal plating layer includes at least one selected from copper (Cu), tin (Sn), and gold (Au).

5. The semiconductor chip of claim 1, wherein the alignment mark protection pattern offsets a height difference between an upper surface of the alignment mark pattern and an upper surface of the second insulating pattern.

6. The semiconductor chip of claim 1, wherein an upper surface of the alignment mark protection pattern is positioned at substantially the same level as an upper surface of the second insulating pattern.

7. The semiconductor chip of claim 1, wherein the redistribution layer pattern and the alignment mark pattern have substantially the same thickness, and
wherein the second insulating pattern and the alignment mark protection pattern have substantially the same thickness.

8. The semiconductor chip of claim 1, wherein the first insulating pattern is disposed to surround the alignment mark pattern.

9. The semiconductor chip of claim 1, wherein the alignment mark pattern and the alignment mark protection pattern are disposed in an edge region on the surface of the chip body.

10. A semiconductor chip comprising:
a chip body;
a redistribution layer pattern and an alignment mark pattern that are disposed to be spaced apart from each other on a surface of the chip body;
an insulating pattern disposed on the redistribution layer pattern; and
an alignment mark protection pattern disposed on the alignment mark pattern,
wherein the alignment mark protection pattern includes a metal material, and
wherein the alignment mark protection pattern offsets a height difference between the alignment mark pattern and the insulating pattern.

11. The semiconductor chip of claim 10, wherein the alignment mark protection pattern is a metal plating layer, and
wherein the metal plating layer includes at least one selected from copper (Cu), tin (Sn), and gold (Au).

12. The semiconductor chip of claim 10, wherein the redistribution layer pattern and the alignment mark pattern include the same metal material.

13. The semiconductor chip of claim 10, wherein an upper surface of the alignment mark protection pattern is positioned at substantially the same level as an upper surface of the insulating pattern.

14. The semiconductor chip of claim 10, wherein the alignment mark protection pattern is disposed to cover the alignment mark pattern on the surface of the chip body.

15. The semiconductor chip of claim 10, wherein the alignment mark pattern and the alignment mark protection pattern are disposed in an edge region on the surface of the chip body.

16. A semiconductor package comprising:
a package substrate; and
a semiconductor chip mounted over the package substrate and including an alignment mark pattern for alignment of the semiconductor chip over the package substrate,
wherein the semiconductor chip comprises:
a chip body;
a redistribution layer pattern disposed on a surface of the chip body;
an alignment mark pattern disposed to be spaced apart from the redistribution layer pattern on the surface of the chip body;
a first insulating pattern disposed to contact a side surface of the redistribution layer pattern and a side surface of the alignment mark pattern on the surface of the chip body;
a second insulating pattern disposed on the redistribution layer pattern to protect the redistribution layer pattern; and
an alignment mark protection pattern disposed on the alignment mark pattern and offsetting a height difference between the second insulating pattern and the alignment mark pattern.

17. The semiconductor package of claim 16, wherein the alignment mark pattern and the alignment mark protection pattern are disposed in an edge region on the surface of the chip body.

18. The semiconductor package of claim 16, wherein each of the alignment mark pattern and the alignment mark protection pattern includes a metal material.

19. The semiconductor package of claim 16, wherein the alignment mark protection pattern is disposed to cover the alignment mark pattern on the surface of the chip body.

20. The semiconductor package of claim 16, wherein the alignment mark protection pattern includes a metal plating layer, and
wherein the metal plating layer includes at least one selected from copper (Cu), tin (Sn), and gold (Au).
